(19) United States
(12) Patent Application Publication
(10) Pub. No.: US 2023/0365860 A1
(43) Pub. Date: Nov. 16, 2023

(54) PHOSPHOR, FLUORESCENT MEMBER, AND LIGHT EMITTING MODULE

(71) Applicant: KOITO MANUFACTURING CO., LTD., Tokyo (JP)

(72) Inventors: Atsushi NAKAMURA, Shizuoka-shi (JP); Hisayoshi DAICHO, Shizuoka-shi (JP); Takeshi IWASAKI, Shizuoka-shi (JP)

(73) Assignee: KOITO MANUFACTURING CO., LTD., Tokyo (JP)

(21) Appl. No.: 18/360,257

(22) Filed: Jul. 27, 2023

Related U.S. Application Data
(63) Continuation of application No. PCT/JP2022/004071, filed on Feb. 2, 2022.

(30) Foreign Application Priority Data
Feb. 3, 2021 (JP) 2021-016058
Jul. 19, 2021 (JP) 2021-118916

(51) Int. Cl. C09K 11/77; C09K 11/55; C09K 11/02

(52) U.S. Cl. CPC C09K 11/77744; C09K 11/55; C09K 11/02

(57) ABSTRACT

A phosphor has a crystal structure of a garnet type and is expressed by a general formula BaₐY_{3-a-b}Al₅₋ₐSiₐO₁₂:Ce_{b} (wherein a and b are values within a range that satisfies 12.0113≤A+0.036b−0.003a≤12.0153, when A denotes a lattice size of the crystal structure, a [mol] denotes an amount of Ba incorporated in solid solution, and b [mol] denotes an amount of Ce incorporated in solid solution).

### BACKGROUND

### 1. Field of the Invention

The present disclosure relates to phosphors.

### 2. Description of the Related Art

Conventionally, a white light source in which a YAG phosphor and a blue LED are combined is widely known. Meanwhile, with an increase in the luminance of light sources, heat concentration caused by wavelength conversion (Stokes loss) in a YAG phosphor leads to thermal quenching, which in turn leads to a decrease in the efficiency of a white light source. Accordingly, BaY_{1.92}Al₄SiO₁₂:Ce_{0.08} in which Ba and Si are incorporated in a YAG phosphor in solid solution has been devised (see non patent document 1). This phosphor has better temperature characteristics than a conventional YAG phosphor (Y₃Al₅O₁₂:Ce) and exhibits a light emission intensity retention rate of 91.5% when its temperature is raised from 25° C. to 200° C., thus this phosphor is less likely to cause thermal quenching.

[non patent document 1] Haipeng Ji et al., “New Y₂BaAl₄SiO₁₂:Ce³⁺ yellow microcrystal-glass powder phosphor with high thermal emission stability,” Journal of Materials Chemistry C, 2016, 4, pp. 9872-9878.

However, there is a limit in the range of chromaticities that can be achieved by the aforementioned yellow phosphor expressed by BaY_{1.92}Al₄SiO₁₂:Ce_{0.08}. Therefore, there is also a limit in the range of chromaticities that can be achieved by a white light source in which this yellow phosphor and a blue LED are combined.

### SUMMARY OF THE INVENTION

A phosphor according to one aspect of the present disclosure has a crystal structure of a garnet type and is expressed by a general formula BaₐY_{3-a-b}Al₅₋ₐSiₐO₁₂:Ce_{b} (wherein a and b are values within a range that satisfies 12.0113≤S+0.036b−0.003a≤12.0153, when S denotes a lattice size of the crystal structure, a [mol] denotes an amount of Ba incorporated in solid solution, and b [mol] denotes an amount of Ce incorporated in solid solution).

Another aspect of the present disclosure provides a fluorescent member. The fluorescent member may include a resin transparent to visible light and a phosphor encapsulated in the resin. The phosphor may be contained in the resin at 0.1 vol % to 30 vol %, and the fluorescent member may have a thickness of 0.01 mm to 5 mm.

It is to be noted that any arbitrary combination or rearrangement of the above-described structural components and so forth is effective as and encompassed by the present embodiments. Moreover, this summary does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a chromaticity diagram (CIE1931) showing the chromaticity of an emission color of a conventional yellow phosphor and blue LED.

FIG. 2 is a diagram for describing a range for a dominant wavelength to be targeted by a yellow phosphor according to an embodiment.

FIG. 3 shows relationships between an amount (b) of Ce incorporated in solid solution and a dominant wavelength λd observed when an amount (a) of Ba incorporated in solid solution is constant.

FIG. 4 shows relationships between an amount (a) of Ba incorporated in solid solution and a dominant wavelength λd observed when an amount (b) of Ce incorporated in solid solution is constant.

FIG. 5 shows relationships between an amount (b) of Ce incorporated in solid solution and a lattice size S observed when an amount (a) of Ba incorporated in solid solution is constant.

FIG. 6 shows relationships between an amount (a) of Ba incorporated in solid solution and a lattice size S observed when an amount (b) of Ce incorporated in solid solution is constant.

FIG. 7 shows relationships between a lattice size S and a dominant wavelength λd observed when an amount of Ba incorporated in solid solution is constant.

FIG. 8 shows relationships between a corrected lattice size S′ and a dominant wavelength λd.

FIG. 9 is a schematic diagram of a light emitting module according to an embodiment.

### DETAILED DESCRIPTION

### Outline of Embodiments

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A phosphor according to one aspect of the present disclosure has a crystal structure of a garnet type and is expressed by a general formula BaₐY_{3-a-b}Al₅₋ₐSiₐO₁₂:Ce_{b} (wherein a and b are values within a range that satisfies 12.0113≤S+0.036b−0.003a≤12.0153, when S denotes a lattice size of the crystal structure, a [mol] denotes an amount of Ba incorporated in solid solution, and b [mol] denotes an amount of Ce incorporated in solid solution).

According to this aspect, a novel phosphor having good light emission characteristics and temperature characteristics can be achieved.

The phosphor may be excited by blue light having a peak wavelength within a range of 430 nm to 480 nm and may emit yellow light having a dominant wavelength within a range of 567 nm to 572 nm. Thus, a novel yellow phosphor can be achieved.

The amount a [mol] of Ba incorporated in solid solution may be no greater than 1.0.

A mean volume diameter may be 1 μm to 30 μm.

Another aspect of the present disclosure provides a fluorescent member. This fluorescent member may include phosphor powder that is powder of the phosphor above, and thermal conduction powder that is powder of a material having a thermal conductivity higher than a thermal conductivity of the phosphor.

According to this aspect, heat dissipation performance of the fluorescent member can be improved.

A volume ratio of the phosphor powder and the thermal conduction powder may be 90:10 to 60:40. Thus, light emission performance of the fluorescent member can be increased while improving the heat dissipation performance of the fluorescent member.

The phosphor powder may absorb light having a peak wavelength of 450 nm, the fluorescent member may have a thickness of 0.12 mm to 0.30 mm, and the fluorescent member may have a transmittance of no less than 70% to light having a wavelength of 550 nm to 600 nm. This makes it possible to achieve light suitable for a desired use (e.g., headlamp) while increasing the mechanical strength of the fluorescent member.

The phosphor powder may absorb blue light having a peak wavelength of 450 nm, and the fluorescent member may have an absorptance of 78% to 88% to the blue light. This makes it possible to achieve light suitable for a desired use (e.g., headlamp).

Yet another aspect of the present disclosure provides a fluorescent member. This fluorescent member includes a resin transparent to visible light and a phosphor encapsulated in the resin. The phosphor may be contained in the resin at 0.1 vol % to 30 vol %, and the fluorescent member may have a thickness of 0.01 mm to 5 mm. This makes it possible to achieve a light emitting module that produces an emission color of a chromaticity within a desired range while achieving a desired light emission efficiency.

Yet another aspect of the present disclosure provides a light emitting module. This light emitting module includes an LED that emits blue light having a peak wavelength within a range of 430 nm to 480 nm, and an optical wavelength conversion layer that is excited by the blue light that the LED emits and emits yellow light. The optical wavelength conversion layer includes the fluorescent member above. This light emitting module has an emission color, resulting from mixing the blue light and the yellow light, of a chromaticity within a range defined by chromaticity coordinates (cx,cy)=(0.311, 0.339), (0.313, 0.342), (0.331, 0.354), (0.331, 0.338), (0.319, 0.315), (0.311, 0.309).

Hereinafter, the present invention will be described based on some exemplary embodiments and with reference to the drawings. Identical or equivalent constituent elements, members, and processes shown in the drawings are given identical reference characters, and duplicate description thereof will be omitted as appropriate. The embodiments are illustrative in nature and are not intended to limit the invention. Not all the features and combinations thereof described in the embodiments are necessarily essential to the invention.

### Phosphor

### Phosphor

A phosphor according to the present embodiment emits light as being excited efficiently by blue light. Specifically, the phosphor exhibits intense excitation by blue light having a peak wavelength within a range of 430 nm to 480 nm, and emits yellow light having a dominant wavelength within a range of 567 nm to 572 nm. The phosphor according to the present embodiment has a crystal structure of a garnet type and achieves yellow light emission as being doped with an activator, such as Ce³⁺ ions.

Next, the phosphor according to the present embodiment will be described in detail. The phosphor according to the present embodiment is expressed by a general formula BaₐY_{3-a-b}Al₅₋ₐSiₐO₁₂:Ce_{b} (in which a and b are values within a range that satisfies 12.0113≤S+0.036b−0.003a≤12.0153, when S denotes the lattice size of the crystal structure, a [mol] denotes the amount of Ba incorporated in solid solution, and b [mol] denotes the amount of Ce incorporated in solid solution). Herein, b may be 0.01 to 0.12. This can further improve the internal quantum efficiency, absorptance, and light emission intensity retention rate of the phosphor.

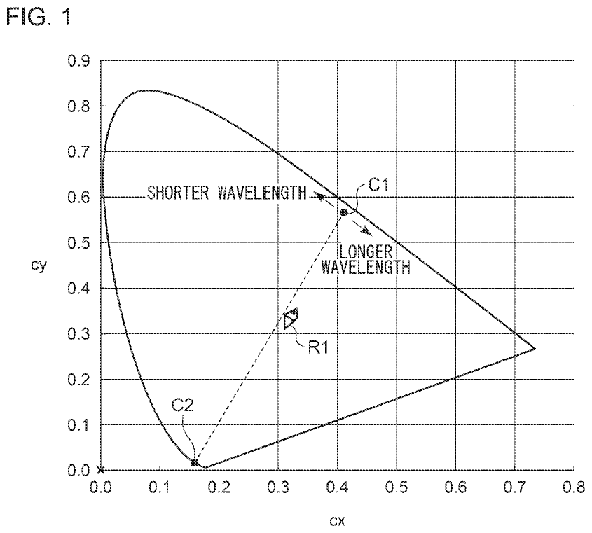

FIG. 1 is a chromaticity diagram (CIE1931) showing the chromaticity of an emission color of a conventional yellow phosphor and blue LED. A point C1 shown in FIG. 1 is the chromaticity coordinates of a known phosphor (BaY_{1.92}Al₄SiO₁₂:Ce_{0.08}) in which Ba and Si are incorporated in a YAG phosphor in solid solution, and this known phosphor has a dominant wavelength of 566.3 nm. Meanwhile, a point C2 is the chromaticity coordinates of one example of a blue LED having a peak wavelength within a range of 430 nm to 480 nm.

A range R1 is a chromaticity range defined as white light for a specific use (vehicle headlight). Specifically, the range R1 is defined by chromaticity coordinates (cx,cy)=(0.311, 0.339), (0.313, 0.342), (0.331, 0.354), (0.331, 0.338), (0.319, 0.315), (0.311, 0.309).

Mixed color light in which yellow light of the known phosphor and blue light of the LED are combined has a chromaticity on the straight line connecting the point C1 and the point C2. Therefore, as shown in FIG. 1, when the dominant wavelength of the yellow light shifts to the longer wavelength side, white light included in the range R1 cannot be achieved unless the blue LED is changed. Accordingly, there arises a demand for, like a yellow phosphor according to the invention of the present application, a phosphor having a dominant wavelength shifted further to the longer wavelength side than the conventional yellow phosphor.

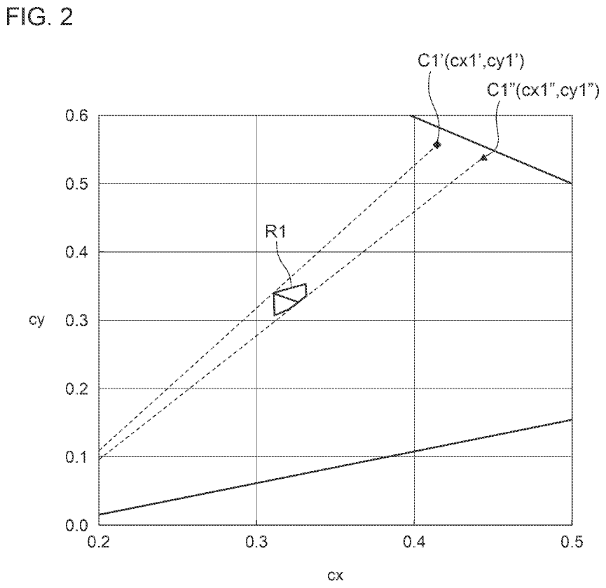

FIG. 2 is a diagram for describing a range for a dominant wavelength to be targeted by the yellow phosphor according to the present embodiment. The yellow phosphor according to the present embodiment, in order to achieve a chromaticity range defined as white light for vehicle headlight when combined with a blue LED, needs a straight line passing the range R1, the straight line connecting a chromaticity (cx2,cy2) of the blue LED and a chromaticity (cx1,cy1) of the yellow phosphor.

According to the examinations conducted by the inventors of the present application, the dominant wavelength observed when a straight line connecting the chromaticity (cx2,cy2) of the blue LED at the point C2 and a chromaticity (cx1′,cy1′) of the yellow phosphor at a point C1′ touches the chromaticity range R1 at its upper portion is 567.4 nm. In a similar manner, the dominant wavelength observed when a straight line connecting the chromaticity (cx2,cy2) of the blue LED at the point C2 and a chromaticity (cx1″,cy1″) of the yellow phosphor at a point C1″ touches the chromaticity range R1 at its lower portion is 570.6 nm.

Therefore, the yellow phosphor according to the present embodiment favorably has a dominant wavelength within a range of 567 nm to 572 nm or preferably has a dominant wavelength within a range of 567.4 nm to 570.6 nm.

More specific description will be provided below based on the result of measuring samples having different phosphor compositions. The following description on the source materials for the phosphors, the manufacturing methods, the chemical compositions of the phosphors, and so forth do not in any way limit the embodiments of the phosphor according to the present invention.

### (Sample 1)

A phosphor according to Sample 1 is expressed by Ba_{1.00}Y_{1.92}Al_{4.00}Si_{1.00}:Ce³⁺_{0.08}. The phosphor according to Sample 1 is manufactured through the following method. First, powder source materials of BaCO₃ (99.9%: manufactured by Kanto Chemical Co., Inc.), Y₂O₃(99.9%: manufactured by Kojundo Chemical Laboratory Co., Ltd.), CeO₂ (99.99%: manufactured by Kojundo Chemical Laboratory Co., Ltd.), α-Al₂O₃(99.99%: manufactured by Kojundo Chemical Laboratory Co., Ltd.), and SiO₂ (99.9%: manufactured by Tokuyama Corporation) are prepared. These powder source materials are then weighted to a molar ratio of Ba=0.01, Y=2.97, Al=4.99, Si=0.01, and Ce=0.02.

As a flux, BaF₂ (99%: manufactured by Kojundo Chemical Laboratory Co., Ltd.) is weighted by 5 wt % of the total weight of the powder source materials and added to the powder source materials, and they are mixed to uniformity in a mortar. Thereafter, the mixture is placed in an alumina crucible (SSA-S B1: manufactured by Nikkato Corporation) and heated for 4 hours at 1550° C. to be sintered in reduced atmosphere (H₂:N₂=5/95 (volume ratio)). The resultant is cooled to room temperature and pulverized in a mortar, and the light emission characteristics of the phosphor excited by light at a wavelength of 460 nm were measured with a spectrophotometer (FP-8500: manufactured by JASCO Corporation).

The result shows that the phosphor according to Sample 1 had a dominant wavelength λd of 567.0 nm, and the light emission intensity retention rate (K) evaluated as the temperature was raised from 25° C. to 200° C. was 89%. In other words, the light emission intensity observed when the temperature was raised to 200° C. dropped to 89% with respect to the light emission intensity observed at 25° C. Furthermore, the internal quantum efficiency (IQE) was 98%, and the absorptance (Abs) at which the phosphor that emitted yellow light absorbed blue light emitted by an LED was 78%.

The results concerning the light emission characteristics, temperature characteristics, and so forth of the phosphor according to Sample 1 are summarized in Table 1. In Table 1, o indicates that the dominant wavelength λd satisfies 567.4 nm≤λd≤570.6 nm, and × indicates that the dominant wavelength λd does not satisfy 567.4 nm λd≤570.6 nm. Furthermore, o indicates that the light emission intensity retention rate (K) is no lower than 90%, and ×indicates that the light emission intensity retention rate (K) is lower than 90%. Furthermore, o indicates that the internal quantum efficiency (IQE) is no lower than 90%, and ×indicates that the internal quantum efficiency (IQE) is lower than 90%. Furthermore, o indicates that the absorptance (Abs) is no lower than 80%, and ×indicates that the absorptance (Abs) is lower than 80%.

TABLE 1

| | | | | | | Dominant | | Light Emission | | | | | |
|---|---|---|---|---|---|---|---|---|---|---|---|---|---|
| | | | | | | Wavelength | | Intensity Retention | | Internal Quantum | | | |
| | | | | | | (λ d) | | Rate (κ) | | Efficiency(IQE) | | Absorptance(Abs) | |
| | Charging Amount (mol) | | | | | | 567.4 [symbol] | κ | | IQE | | Abs | |
| Sample | Ba | Y | Al | Si | Ce | λ | λ d [symbol] | (Measured) | κ [symbol] | (Measured | IQE [symbol] | (Measured | Abs [symbol] |
| No. | a | 3-a-b | 5-a | a | b | d(nm) | 570.8 | Value) | 0.90 | Value) | 0.90 | Value) | 0.80 |
| 1 | 0.01 | 2.97 | 4.99 | 0.01 | 0.02 | 567.0 | x | 89% | x | 98% | ∘ | 78% | x |
| 2 | 0.01 | 2.95 | 4.99 | 0.01 | 0.04 | 568.0 | ∘ | 89% | x | 94% | ∘ | 80% | ∘ |
| 3 | 0.01 | 2.93 | 4.99 | 0.01 | 0.0 [symbol] | 570.4 | ∘ | 87% | x | 96% | ∘ | 84% | ∘ |
| 4 | 0.03 | 2.94 | 4.97 | 0.03 | 0.03 | 567.4 | ∘ | 95% | ∘ | [symbol] | ∘ | 81% | ∘ |
| 5 | 0.03 | 2.93 | 4.97 | 0.03 | 0.04 | 568.8 | ∘ | 94% | ∘ | 98% | ∘ | 82% | ∘ |
| 6 | 0.03 | 2.91 | 4.97 | 0.03 | 0.06 | 570.2 | ∘ | 93% | ∘ | 97% | ∘ | 84% | ∘ |
| 7 | 0.05 | 2.92 | 4.95 | 0.05 | 0.03 | 567.3 | x | 95% | ∘ | 98% | ∘ | 82% | ∘ |
| 8 | 0.05 | 2.91 | 4.95 | 0.05 | 0.04 | 567.8 | ∘ | 95% | ∘ | 98% | ∘ | 82% | ∘ |
| 9 | 0.05 | 2.89 | 4.95 | 0.05 | 0.06 | 569.0 | ∘ | [symbol] | ∘ | 97% | ∘ | 84% | ∘ |
| 10 | 0.0 [symbol] | 2.87 | 4.95 | 0.05 | 0.08 | 570.6 | ∘ | 91% | ∘ | 97% | ∘ | 85% | ∘ |
| 11 | 0.05 | 2.86 | 4.95 | 0.05 | 0.09 | 570.7 | x | 90% | ∘ | 97% | ∘ | 85% | ∘ |
| 12 | 0.08 | 2.89 | 4.92 | 0.08 | 0.03 | 567.4 | ∘ | 92% | ∘ | 98% | ∘ | 82% | ∘ |
| 13 | 0.08 | 2.86 | 4.92 | 0.08 | 0.06 | 568.9 | ∘ | 91% | ∘ | 98% | ∘ | 84% | ∘ |
| 14 | 0.08 | 2.84 | 4.92 | 0.08 | 0.08 | 570.4 | ∘ | 90% | ∘ | 97% | ∘ | 85% | ∘ |
| 15 | 0.10 | 2.86 | 4.90 | 0.10 | 0.04 | 567.4 | ∘ | 93% | ∘ | 98% | ∘ | 82% | ∘ |
| 16 | 0.10 | 2. [symbol] 4 | 4.90 | 0.10 | 0.05 | 568.7 | ∘ | 92% | ∘ | 97% | ∘ | 84% | ∘ |
| 17 | 0.10 | 2.81 | 4.90 | 0.10 | 0.09 | 570. [symbol] | ∘ | 90% | ∘ | 94% | ∘ | 86% | ∘ |
| 18 | 0.10 | 2.80 | 4.90 | 0.10 | 0.10 | 570.7 | x | 88% | x | 92% | ∘ | 86% | ∘ |
| 19 | 0.20 | 2.77 | 4.80 | 0.20 | 0.03 | 567.1 | x | 93% | ∘ | 97% | ∘ | 82% | ∘ |
| 20 | 0.20 | 2.75 | 4.80 | 0.20 | 0.04 | 567.4 | ∘ | 93% | ∘ | 9 [symbol] % | ∘ | 82% | ∘ |
| 21 | 0.20 | 2.72 | 4.80 | 0.20 | 0.08 | 569.0 | ∘ | 91% | ∘ | 97% | ∘ | 85% | ∘ |
| 22 | 0.20 | 2.70 | 4.80 | 0.20 | 0.10 | 570.6 | ∘ | 90% | ∘ | 93% | ∘ | 86% | ∘ |
| 23 | 0.20 | 2. [symbol] | 4.80 | 0.20 | 0.13 | 570.7 | x | [symbol] 8% | x | 91% | ∘ | 85% | ∘ |
| 24 | 0.40 | 2.55 | 4.60 | 0.40 | 0.05 | 567.2 | x | 92% | ∘ | 97% | ∘ | 84% | ∘ |
| 25 | 0.40 | 2. [symbol] | 4. [symbol] 0 | 0.40 | 0.08 | 567.4 | ∘ | 92% | ∘ | 97% | ∘ | 84% | ∘ |
| 26 | 0.40 | 2.50 | 4.60 | 0.40 | 0.10 | 568.6 | ∘ | 91% | ∘ | 93% | ∘ | 86% | ∘ |
| 27 | 0.40 | 2.46 | 4.50 | 0.40 | 0.14 | 569.9 | ∘ | 85% | x | 90% | ∘ | 8 [symbol] % | ∘ |
| 28 | 0.40 | 2.45 | 4.60 | 0.40 | 0.15 | 570.4 | ∘ | 84% | x | [symbol] % | x | 86% | ∘ |
| 29 | 0.40 | 2.44 | 4.50 | 0.40 | 0.16 | 570.8 | x | 84% | x | 88% | x | [symbol] % | ∘ |
| 30 | 0.60 | 2.31 | 4.40 | 0.60 | 0.09 | 567.3 | x | 90% | ∘ | 92% | ∘ | 86% | ∘ |
| 31 | 0.60 | 2.30 | 4.40 | 0.60 | 0.10 | [symbol] | ∘ | 90% | ∘ | 92% | ∘ | 86% | ∘ |
| 32 | 0.60 | 2.25 | 4.40 | 0.60 | 0.14 | 569.0 | ∘ | 88% | x | 88% | x | 86% | ∘ |
| 33 | 0.60 | 2.22 | 4.40 | 0.60 | 0.18 | [symbol] 70.7 | x | 85% | x | 82% | x | 86% | ∘ |
| 34 | 0.50 | 2.21 | 4.40 | 0.60 | 0.19 | 570.7 | x | 85% | x | 81% | x | 86% | ∘ |
| 35 | 1.00 | 1.92 | 4.00 | 1.00 | 0.08 | 566.3 | x | 92% | ∘ | 95% | ∘ | 80% | ∘ |

[symbol]

indicates data missing or illegible when filed

### (Samples 2 to 35)

Phosphors according to Samples 2 to 35 are expressed by a general formula BaₐY_{3-a-b}Al₅₋ₐSiₐO₁₂:Ce_{b}. Except that powder source materials like those of Sample 1 were weighted to the charging amounts indicated for each sample in Table 1, the phosphorus were fabricated under conditions similar to those of Sample 1, and the light emission characteristics, temperature characteristics, and so forth the phosphors were evaluated. The results are shown in Table 1. In this manner, in many of the samples, a novel phosphor having good light emission characteristics and temperature characteristics was achieved. The amount a [mol] of Ba incorporated in solid solution is favorably no greater than 1.0, preferably no greater than 0.6, or more preferably no greater than 0.4.

Comparable light emission characteristics were obtained also with a phosphor synthesized with its source materials mixed through a liquid phase mixing method, such as a citric acid sol-gel method, a hexamine method, or a urea method. Various techniques can be employed for the method of manufacturing the phosphor according to the present embodiment. When, for example, a solid phase method is used, the use of high-purity powder source materials can keep impurities from mixing in, and the source materials can be mixed in a short time (about 10 minutes). The use of a liquid phase method allows for mixing at an atomic level, and this makes it possible to create phosphors that differ in their compositions at the level of 1/100 mol.

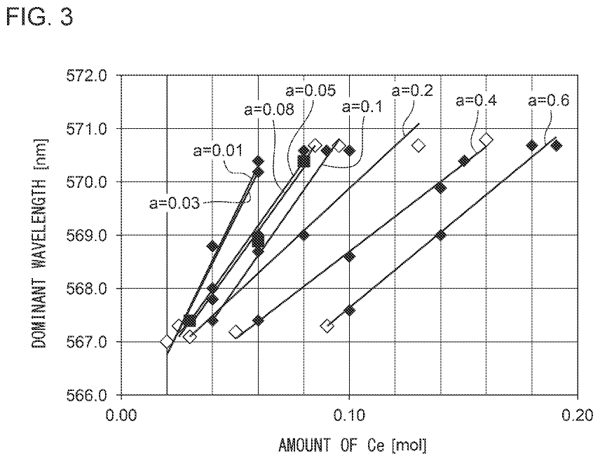

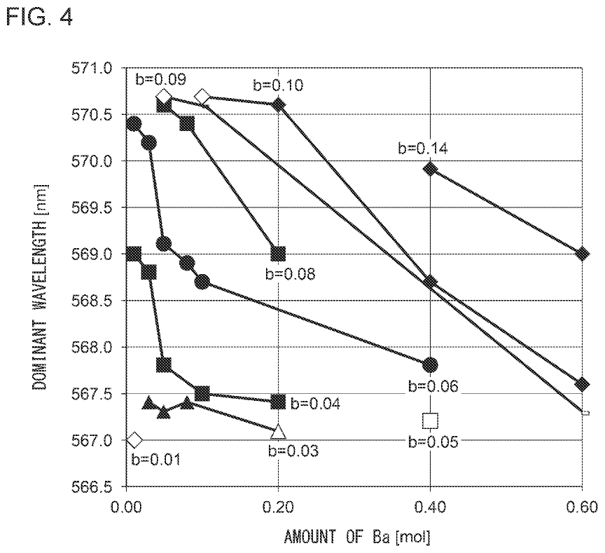

FIG. 3 shows relationships between the amount (b) of Ce incorporated in solid solution and the dominant wavelength λd observed when the amount (a) of Ba incorporated in solid solution is constant. FIG. 4 shows relationships between the amount (a) of Ba incorporated in solid solution and the dominant wavelength λd observed when the amount (b) of Ce incorporated in solid solution is constant. The solid white marks shown in FIGS. 3 and 4 represent samples of which the dominant wavelength λd does not satisfy the range 567.4 nm≤λd≤570.6 nm.

FIG. 3 shows that, when the amount of Ba incorporated in solid solution is constant, the dominant wavelength shifts to the longer wavelength side as the amount of Ce incorporated in solid solution increases. Meanwhile, FIG. 4 shows that, when the amount of Ce incorporated in solid solution is constant, the dominant wavelength shifts to the shorter wavelength side as the amount of Ba incorporated in solid solution increases. In other words, these figures show that, in order to bring the dominant wavelength into a desired range, the amount of Ce incorporated in solid solution needs to be increased along with an increase in the amount of Ba incorporated in solid solution.

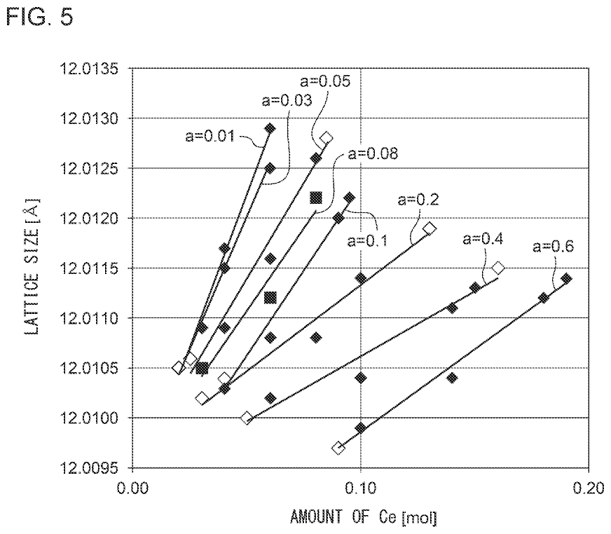

FIG. 5 shows relationships between the amount (b) of Ce incorporated in solid solution and the lattice size S observed when the amount (a) of Ba incorporated in solid solution is constant. FIG. 6 shows relationships between the amount (a) of Ba incorporated in solid solution and the lattice size S observed when the amount (b) of Ce incorporated in solid solution is constant. Herein, the lattice size S is a measured value of the phosphor expressed by a general formula BaₐY_{3-a-b}Al₅₋ₐSiₐO₁₂:Ce_{b}. The lattice size S was calculated with use of XRD measurement data analyzing software (PDXL-II) manufactured by Rigaku Corporation. The solid white marks shown in FIGS. 5 and 6 represent samples of which the dominant wavelength λd does not satisfy the range 567.4 nm≤λd≤570.6 nm. The lattice size S, a measured value of each sample, is shown in Table 2.

TABLE 2

| | Charging Amount (mol) | | | | | Lattice Size S | Corrected Lattice Size S′ | |
|---|---|---|---|---|---|---|---|---|
| Sample | Ba | Y | Al | Si | Ce | S(Å: Measured | S′(Å: Calculated | 12.0113 ≤ |
| No. | a | 3-a-b | 5-a | a | b | Value) | Value) | S′ ≤ 12.0153 |
| 1 | 0.01 | 2.97 | 4.99 | 0.01 | 0.02 | 12.0105 | 12.0112 | x |
| 2 | 0.01 | 2.95 | 4.99 | 0.01 | 0.04 | 12.0115 | 12.0129 | ∘ |
| 3 | 0.01 | 2.93 | 4.99 | 0.01 | 0.06 | 12.0129 | 12.0150 | ∘ |
| 4 | 0.03 | 2.94 | 4.97 | 0.03 | 0.03 | 12.0109 | 12.0119 | ∘ |
| 5 | 0.03 | 2.93 | 4.97 | 0.03 | 0.04 | 12.0117 | 12.0131 | ∘ |
| 6 | 0.03 | 2.91 | 4.97 | 0.03 | 0.06 | 12.0125 | 12.0416 | ∘ |
| 7 | 0.05 | 2.92 | 4.95 | 0.05 | 0.03 | 12.0106 | 12.0112 | x |
| 8 | 0.05 | 2.91 | 4.95 | 0.05 | 0.04 | 12.0109 | 12.0122 | ∘ |
| 9 | 0.05 | 2.89 | 4.95 | 0.05 | 0.06 | 12.0116 | 12.0136 | ∘ |
| 10 | 0.05 | 2.87 | 4.95 | 0.05 | 0.08 | 12.0126 | 12.0153 | ∘ |
| 11 | 0.05 | 2.86 | 4.95 | 0.05 | 0.09 | 12.0128 | 12.0157 | x |
| 12 | 0.08 | 2.89 | 4.92 | 0.08 | 0.03 | 12.0105 | 12.0113 | ∘ |
| 13 | 0.08 | 2.86 | 4.92 | 0.08 | 0.06 | 12.0112 | 12.0131 | ∘ |
| 14 | 0.08 | 2.84 | 4.92 | 0.08 | 0.08 | 12.0122 | 12.0148 | ∘ |
| 15 | 0.10 | 2.86 | 4.90 | 0.10 | 0.04 | 12.0104 | 12.0115 | ∘ |
| 16 | 0.10 | 2.84 | 4.90 | 0.10 | 0.06 | 12.0108 | 12.0127 | ∘ |
| 17 | 0.10 | 2.81 | 4.90 | 0.10 | 0.09 | 12.0120 | 12.0149 | ∘ |
| 18 | 0.10 | 2.80 | 4.90 | 0.10 | 0.10 | 12.0122 | 12.0155 | x |
| 19 | 0.20 | 2.77 | 4.80 | 0.20 | 0.03 | 12.0102 | 12.0107 | x |
| 20 | 0.20 | 2.76 | 4.80 | 0.20 | 0.04 | 12.0103 | 12.0113 | ∘ |
| 21 | 0.20 | 2.72 | 4.80 | 0.20 | 0.08 | 12.0108 | 12.0131 | ∘ |
| 22 | 0.20 | 2.70 | 4.80 | 0.20 | 0.10 | 12.0114 | 12.0144 | ∘ |
| 23 | 0.20 | 2.67 | 4.80 | 0.20 | 0.13 | 12.0119 | 12.0160 | x |
| 24 | 0.40 | 2.55 | 4.60 | 0.40 | 0.05 | 12.0100 | 12.0110 | x |
| 25 | 0.40 | 2.54 | 4.60 | 0.40 | 0.06 | 12.0102 | 12.0115 | ∘ |
| 26 | 0.40 | 2.50 | 4.60 | 0.40 | 0.10 | 12.0104 | 12.0128 | ∘ |
| 27 | 0.40 | 2.46 | 4.60 | 0.40 | 0.14 | 12.0111 | 12.0149 | ∘ |
| 28 | 0.40 | 2.45 | 4.60 | 0.40 | 0.15 | 12.0113 | 12.0153 | ∘ |
| 29 | 0.40 | 2.44 | 4.60 | 0.40 | 0.16 | 12.0115 | 12.0161 | x |
| 30 | 0.60 | 2.31 | 4.40 | 0.60 | 0.09 | 12.0097 | 12.0111 | x |
| 31 | 0.60 | 2.30 | 4.40 | 0.60 | 0.10 | 12.0099 | 12.0117 | ∘ |
| 32 | 0.60 | 2.26 | 4.40 | 0.60 | 0.14 | 12.0104 | 12.0136 | ∘ |
| 33 | 0.60 | 2.22 | 4.40 | 0.60 | 0.18 | 12.0112 | 12.0159 | x |
| 34 | 0.60 | 2.21 | 4.40 | 0.60 | 0.19 | 12.0114 | 12.0164 | x |
| 35 | 1.00 | 1.92 | 4.00 | 1.00 | 0.08 | 12.0050 | 12.0049 | x |

As shown in FIG. 5, when the amount of Ba incorporated in solid solution is constant, the lattice size S tends to increase along with an increase in the amount of Ce incorporated in solid solution. Meanwhile, as shown in FIG. 6, when the amount of Ce incorporated in solid solution is constant, the lattice size S tends to decrease along with an increase in the amount of Ba incorporated in solid solution. However, the influence of the amount of Ba incorporated in solid solution on the lattice size S and the influence of the amount of Ce incorporated in solid solution on the lattice size S differ from each other. Specifically, based on the result of the approximation lines shown in FIG. 5, when the amount of Ce incorporated in solid solution increases by 1 mol, the lattice size S increases by 0.036 Å. Meanwhile, based on the result of the approximation lines shown in FIG. 6, when the amount of Ba incorporated in solid solution increases by 1 mol, the lattice size S decreases by 0.003 Å.

Thus, a lattice size that results in a dominant wavelength of a yellow phosphor suitable for a white light source of a vehicle headlamp was calculated as a simulatively corrected lattice size S′. When S denotes the measured lattice size, a (mol) denotes the amount of Ba incorporated in solid solution, and b (mol) denotes the amount of Ce incorporated in solid solution, the corrected lattice size S′ was assumed to be S′=S+0.036b−0.003a. The corrected lattice size S′ of each sample is shown in Table 2.

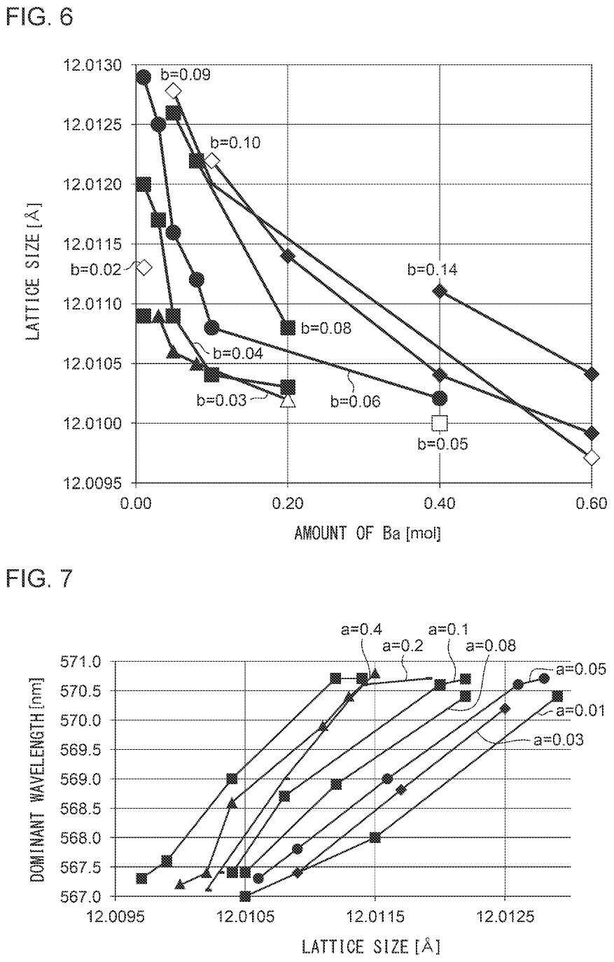

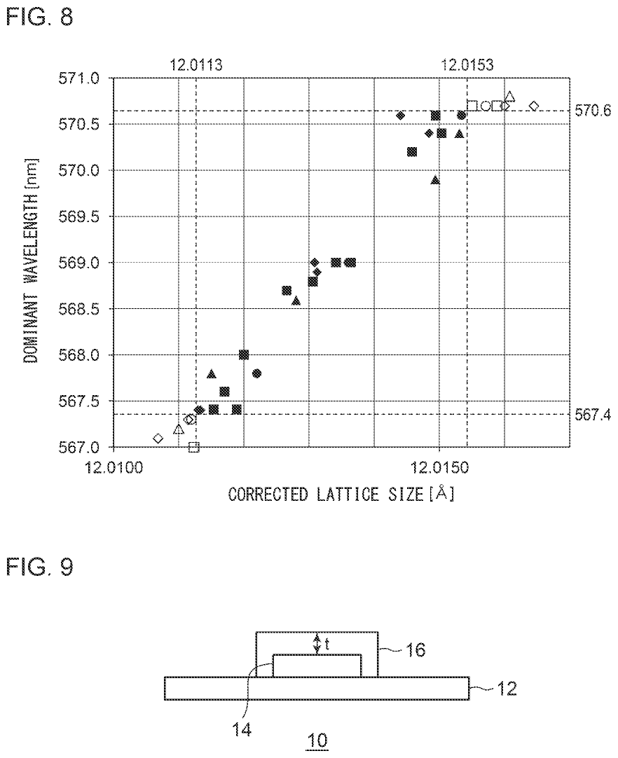

FIG. 7 shows relationships between the lattice size S and the dominant wavelength λd observed when the amount of Ba incorporated in solid solution is constant. FIG. 8 shows relationships between the corrected lattice size S′ and the dominant wavelength λd. FIG. 7 shows that the dominant wavelength λd shifts to the longer wavelength side as the lattice size S increases.

Then, plotting the relationships between the corrected lattice size S′ and the dominant wavelength λd with the amount (a) of Ba incorporated in solid solution and the amount (b) of Ce incorporated in solid solution reflected thereon shows that the corrected lattice size S′ held when the dominant wavelength λd is within the range 567.4 nm≤λd≤570.6 nm needs to satisfy 12.0113≤S′≤12.0153, as shown in FIG. 8. In other words, it has become apparent that, when the amount (a) of Ba incorporated in solid solution and the amount (b) of Ce incorporated in solid solution satisfy 12.0113≤S+0.036b−0.003a≤12.0153, a yellow phosphor that emits light at a desired dominant wavelength and that is expressed by a general formula BaₐY_{3-a-b}Al₅₋ₐSiₐO₁₂:Ce_{b} can be obtained.

### Light Emitting Module

FIG. 9 is a schematic diagram of a light emitting module according to the present embodiment. A light emitting module 10 according to the present embodiment includes a mounting board 12, an LED 14 that is a light emitting element mounted on the mounting board 12, and an optical wavelength conversion layer 16 in which a phosphor is dispersed in a resin. The LED 14 emits blue light having a peak wavelength within a range of 430 nm to 480 nm. In the optical wavelength conversion layer 16, the yellow phosphor according to the present embodiment is dispersed in a silicone resin that is transparent to visible light. The optical wavelength conversion layer 16 contains the yellow phosphor at 0.1 vol % to 30 vol % and has a thickness t of 0.01 mm to 5 mm. The thickness may be in a range of 0.1 mm to 2 mm. The yellow phosphor may have a volume concentration of no greater than 10 vol %. The yellow phosphor may have a mean volume diameter (MV) of 1 μm to 30 μm.

This light emitting module 10 includes the optical wavelength conversion layer 16 that emits yellow light upon being excited by the blue light that the LED 14 emits. The optical wavelength conversion layer 16 includes the phosphor described above. This light emitting module 10 has an emission color, resulting from mixing the blue light and the yellow light, of a chromaticity within a range defined by chromaticity coordinates (cx,cy)=(0.311, 0.339), (0.313, 0.342), (0.331, 0.354), (0.331, 0.338), (0.319, 0.315), (0.311, 0.309). This makes it possible to achieve the light emitting module 10 with an emission color having a chromaticity within a range suitable for the headlamp mentioned earlier, while achieving a desired light emission efficiency.

The optical wavelength conversion layer 16 may be a ceramic plate having a thickness of 0.01 mm to 2.0 mm. This ceramic plate is transparent to visible light and is obtained by compression-molding a phosphor and then sintering the phosphor in vacuum or under pressure. In the light emitting module 10, the LED 14 and the optical wavelength conversion layer 16 may be bonded to each other at normal temperature.

In a specific method of manufacturing the ceramic plate, for example, 5 g of the phosphor according to Sample 9 (λd=569.0 nm), TEOS (tetraethoxysilane) of 0.5 wt %, and 50 g of an alumina ball of ϕ1 mm were placed in a 100-ml polypot and rotated for 24 hours. Then, the resultant was removed to an aluminum vat coated with a fluoroplastic and was heat-dried. The dried product was picked apart through nylon 50 mesh pass and then weighted by 1 gram each, and each gram of the resultant was placed in a mold of ϕ22 mm, molded at 10 MPa, and further molded at 98 MPa through cold isostatic pressing (CIP).

The molded product was heated in a vacuum furnace for 24 hours at 1×10⁻³ Pa and at 1750° C. and further heated for 2 hours at 196 MPa and at 1650° C. through hot isostatic pressing (HIP) to obtain a transparent sintered body (transparent ceramic plate) having a thickness of about 1 mm. This transparent sintered body was polished to a desired thickness through mirror surface polishing, pieces each measuring 1 mm each side were cut out therefrom, and a piece was bonded to a blue LED at normal temperature. Thus, the light emitting module according to the present embodiment that achieves white light was fabricated.

### Sintered Body That Includes Phosphor Powder

A sintered body serving as one example of a fluorescent member that includes phosphor powder, powder of the phosphor described above, will be described in further detail. The sintered body may be fabricated with use of various known sintering techniques. For example, phosphor powder may be charged into a mold to be molded, and the obtained molded body may be subjected to CIP, HIP, or the like to fabricate a sintered body.

The sintered body may include various materials as needed, in addition to the phosphor powder, and may include, for example, thermal conduction powder, powder of a material having a thermal conductivity higher than the thermal conductivity of the phosphor. This material may be, for example but not limited to, aluminum nitride (AlN), which is a dielectric body having a thermal conductivity of about 170 W/mK, or aluminum oxide (Al₂O₃), which has a thermal conductivity of about 20 W/mK. As the sintered body includes the thermal conduction powder in addition to the phosphor powder, heat produced when the sintered body emits light can be diffused more quickly than in a case in which the sintered body does not include any thermal conduction powder. According to the present embodiment, heat dissipation performance of the sintered body can be improved, and thus even when the sintered body is mounted on a high-luminance LED, a rise in the temperature at light emission can be suppressed, and a decrease in the light emission performance at high temperature can be suppressed.

The volume ratio of the phosphor powder and thermal conduction powder included in the sintered body is preferably 90:10 to 60:40. When the volume fraction of the thermal conduction powder is no less than 10 vol % and the volume fraction of the phosphor powder is no greater than 90 vol %, heat dissipation performance of the sintered body can be improved. When the volume fraction of the thermal conduction powder is no greater than 40 vol % and the volume fraction of the phosphor powder is no less than 60 vol %, the absorptance of light by the sintered body (e.g., blue light having a peak wavelength of 450 nm) and the transmittance of light through the sintered body (e.g., yellow light having a wavelength of 550 nm to 600 nm) can be increased. The volume ratio as used in the present specification means the volume ratio with respect to the total volume of the phosphor powder and thermal conduction powder included in a fluorescent member, such as the sintered body.

There is no particular limitation on the shape of the sintered body. The sintered body can be processed into various shapes, and the sintered body may have a plate-like shape having a predetermined thickness. The sintered body may have a shape having a predetermined thickness for use, for example, as the optical wavelength conversion layer shown in FIG. 6.

There is no particular limitation on the thickness of the sintered body, and the thickness of the sintered body is preferably 120 μm to 300 μm (0.12 mm to 0.30 mm). When the sintered body has a thickness of no less than 120 μm, the mechanical strength of the sintered body can be increased. This makes the sintered body less breakable and easier to handle. When the sintered body has a thickness of no greater than 300 μm, light directed onto the sintered body from an LED can be kept from leaking through a side surface of the sintered body, and the effective luminous flux of the sintered body can be increased.

The sintered body may transmit light at various wavelengths and may transmit light having a wavelength of, for example, 550 nm to 600 nm. The transmittance of light (e.g., light having a wavelength of 550 nm to 600 nm) through the sintered body may be no lower than 70%. The sintered body (more specifically, the phosphor included in the sintered body) may absorb light at various wavelengths and may absorb blue light having a peak wavelength of, for example, 450 nm. The absorptance of the blue light by the sintered body may be, for example, 78% to 88%. This makes it possible to achieve a light source that emits white light suitable for a desired use (e.g., headlamp) through a combination of a light source (e.g., LED) that emits blue light and a fluorescent member. For example, combining a blue LED and a fluorescent member can achieve a light source that emits white light having a chromaticity within the range defined by chromaticity coordinates (cx,cy)=(0.311, 0.339), (0.313, 0.342), (0.331, 0.354), (0.331, 0.338), (0.319, 0.315), (0.311, 0.309).

Based on examples, a sintered body that includes phosphor powder will be described more specifically.

### (Sample 36)

A phosphor used for Sample 36 is expressed by Ba_{0.04}Y_{2.91}Al_{4.96}Si_{0.04}O₁₂:Ce³⁺_{0.05}. First, powder source materials of BaCO₃ (99.9%), Y₂O₃(99.9%), α-Al₂O₃(99.99%), SiO₂, and CeO₂ (99.99%) were prepared. These powder source materials were then weighted to a molar ratio of Ba=0.04, Y=2.91, Al=4.96, Si=0.04, and Ce=0.05.

As a flux, BaF₂ (99%) was weighted to 5 wt % of the total weight of the powder source materials, BaF₂ was added to the powder source materials, and they were mixed to uniformity in a mortar to obtain mixed powder. Thereafter, the mixed powder was placed in an alumina crucible (SSA-S B1: manufactured by Nikkato Corporation), and the mixed powder was heated for 4 hours at 1550° C. to be sintered in reduced atmosphere (H₂:N₂=5/95 (volume ratio)) to obtain the phosphor. Thereafter, the phosphor was cooled to room temperature, and the phosphor was pulverized with use of a mortar to obtain phosphor powder having a particle size of 1 μm to 30 μm.

The obtained phosphor powder and AlN powder (99.9%) were weighted to a volume ratio of 90:10. Then, with use of a ball mill, the phosphor powder and the AlN powder were mixed and pulverized such that these powders have a particle size of no greater than 3 μm.

The powder obtained through the mixing and pulverizing was charged into a mold of ϕ20 mm, and the powder was molded at a molding pressure of 10 MPa to obtain a primary molded body. Then, the primary molded body was compression-molded with use of CIP at a molding pressure of 98 MPa to obtain a secondary molded body. Then, the secondary molded body was heated for 24 hours at 1650° C. in nitrogen atmosphere of 1×10⁻³ Pa with use of a heating furnace. The heated secondary molded body was further heated for 24 hours at 1550° C. and at 196 MPa through HIP to obtain a sintered body. Then, with use of an abrasive paper, the obtained sintered body was ground and polished and adjusted to a thickness of 100 μm, and the resultant was cut to a piece measuring 1 mm on each side to fabricate a sample of a plate-shaped sintered body.

The thermal conductivity of the samples was measured through a steady state method with use of a thermal conductivity gauge. With the reference value of the thermal conductivity set to 30 W/mK, a sample having a measured value that was no lower than this reference value was evaluated to have a good thermal conductivity.

The transmittance of the samples was measured with use of a spectrophotometer (manufactured by Hitachi, Ltd.). The wavelength of excitation light was set to 460 nm, and the light to be measured was yellow light having a wavelength of 600 nm. A sample was evaluated to have a good transmittance when the transmittance of the yellow light was no lower than 70%.

The absorptance of the samples was measured with use of an integrating sphere. The excitation light was blue light having a wavelength of 460 nm. A sample was evaluated to have a good absorptance when the absorptance of the blue light was 78% to 88%.

The effective luminous flux of the samples was measured with use of an illuminometer. Specifically, a plate-shaped sample was placed on an LED chip that emitted excitation light at 460 nm, the LED chip was caused to emit the excitation light, and only the immediate top and a side surface of each sample were measured to calculate the effective luminous flux. A sample was evaluated to have a good effective luminous flux when the amount of light that leaked through a side surface of the sample was no greater than 10%.

A sample was evaluated to have a good handleability when the sample sustained no damage when handled with tweezers.

A sample was regarded to have a good overall evaluation when the sample was evaluated to have a good thermal conductivity, transmittance, absorptance, handleability, and effective luminous flux.

The fabrication conditions and evaluation results of the samples are summarized in Table 3. In Table 3, regarding the evaluation of the thermal conductivity, o indicates that the measured value is no lower than 30 W/mK, and ×indicates that the measured value is lower than 30 W/mK. Regrading the evaluation of the transmittance, o indicates that the measured value is no lower than 70%, and ×indicates that the measured value is lower than 70%. Regrading the evaluation of the absorptance, o indicates that the measured value is between 78% and 88%, and ×indicates that the measured value is not between 78% and 88%. Regarding the evaluation of the handleability, o indicates that the sample sustains no damage when handled with tweezers, and × indicates that the sample sustains damage when handled with tweezers. Regarding the evaluation of the effective luminous flux, o indicates that the amount of light that leaks through a side surface of the sample in the measurement is no greater than 10%, and × indicates that the amount of light that leaks through a side surface of the sample exceeds 10%. Regarding the overall evaluation, o means the overall evaluation is good, and ×means that the overall evaluation is not good.

TABLE 3

| | Condition | | | | Evaluation Items | |
|---|---|---|---|---|---|---|
| | | Volume | Volume | | Thermal | |
| | Material of | Fraction of | Fraction of | | Conductivity | |
| | Thermal | Phosphor | Thermal | | Measured | |
| Sample | Conduction | Powder | Conduction | Thickness | Value | |
| No. | Powder | [vol. %] | Powder[vol. %] | [μm] | [W/mK] | Evaluation |
| 36 | AlN | 90 | 10 | 100 | 30 | ∘ |
| 37 | AlN | 90 | 10 | 120 | 30 | ∘ |
| 38 | AlN | 90 | 10 | 180 | 30 | ∘ |
| 39 | AlN | 90 | 10 | 240 | 30 | ∘ |
| 40 | AlN | 90 | 10 | 300 | 30 | ∘ |
| 41 | AlN | 90 | 10 | 360 | 30 | ∘ |
| 42 | AlN | 70 | 30 | 100 | 55 | ∘ |
| 43 | AlN | 70 | 30 | 120 | 55 | ∘ |
| 44 | AlN | 70 | 30 | 180 | 55 | ∘ |
| 45 | AlN | 70 | 30 | 240 | 55 | ∘ |
| 46 | AlN | 70 | 30 | 300 | 55 | ∘ |
| 47 | AlN | 70 | 30 | 360 | 55 | ∘ |
| 48 | AlN | 60 | 40 | 100 | 69 | ∘ |
| 49 | AlN | 60 | 40 | 120 | 69 | ∘ |
| 50 | AlN | 60 | 40 | 180 | 69 | ∘ |
| 51 | AlN | 60 | 40 | 240 | 69 | ∘ |
| 52 | AlN | 60 | 40 | 300 | 69 | ∘ |
| 53 | AlN | 60 | 40 | 360 | 69 | ∘ |
| 54 | AlN | 50 | 50 | 100 | 83 | ∘ |
| 55 | AlN | 50 | 50 | 120 | 83 | ∘ |
| 56 | AlN | 50 | 50 | 180 | 83 | ∘ |
| 57 | AlN | 50 | 50 | 240 | 83 | ∘ |
| 58 | AlN | 50 | 50 | 300 | 83 | ∘ |
| 59 | AlN | 50 | 50 | 360 | 83 | ∘ |
| 60 | None | 100 | 0 | 180 | 15 | x |
| 61 | Al₂O₃ | 70 | 30 | 180 | 20 | x |

| | Evaluation Items | | | | | | |
|---|---|---|---|---|---|---|---|
| | Transmittance | | Absorptance | | | | |
| | Measured | | Measured | | | Effective | |
| Sample | Value | | Value | | Handle- | Luminous | Overall |
| No. | [%] | Evaluation | [%] | Evaluation | ability | Flux | Evaluation |
| 36 | 89 | ∘ | 82 | ∘ | x | ∘ | x |
| 37 | 88 | ∘ | 82 | ∘ | ∘ | ∘ | ∘ |
| 38 | 84 | ∘ | 84 | ∘ | ∘ | ∘ | ∘ |
| 39 | 80 | ∘ | 86 | ∘ | ∘ | ∘ | ∘ |
| 40 | 76 | ∘ | 88 | ∘ | ∘ | ∘ | ∘ |
| 41 | 72 | ∘ | 90 | x | ∘ | x | x |
| 42 | 88 | ∘ | 80 | ∘ | x | ∘ | x |
| 43 | 87 | ∘ | 80 | ∘ | ∘ | ∘ | ∘ |
| 44 | 83 | ∘ | 81 | ∘ | ∘ | ∘ | ∘ |
| 45 | 78 | ∘ | 83 | ∘ | ∘ | ∘ | ∘ |
| 46 | 73 | ∘ | 85 | ∘ | ∘ | ∘ | ∘ |
| 47 | 69 | x | 86 | ∘ | ∘ | x | x |
| 48 | 86 | ∘ | 78 | ∘ | x | ∘ | x |
| 49 | 86 | ∘ | 79 | ∘ | ∘ | ∘ | ∘ |
| 50 | 82 | ∘ | 80 | ∘ | ∘ | ∘ | ∘ |
| 51 | 77 | ∘ | 81 | ∘ | ∘ | ∘ | ∘ |
| 52 | 71 | ∘ | 83 | ∘ | ∘ | ∘ | ∘ |
| 53 | 67 | x | 84 | ∘ | ∘ | x | x |
| 54 | 84 | ∘ | 73 | x | x | ∘ | x |
| 55 | 82 | ∘ | 73 | x | ∘ | ∘ | x |
| 56 | 81 | ∘ | 75 | x | ∘ | ∘ | x |
| 57 | 76 | ∘ | 76 | x | ∘ | ∘ | x |
| 58 | 71 | ∘ | 77 | x | ∘ | ∘ | x |
| 59 | 66 | x | 82 | ∘ | ∘ | x | x |
| 60 | 9 [symbol] | ∘ | 82 | ∘ | ∘ | ∘ | x |
| 61 | 95 | ∘ | 78 | ∘ | ∘ | ∘ | x |

[symbol]

indicates data missing or illegible when filed

### (Samples 37 to 41)

For Samples 37 to 41, sintered body samples were fabricated in a similar manner to Sample 36 except that the thickness of the samples was changed to 120 μm, 180 μm, 240 μm, 300 μm, or 360 μm.

### (Samples 42 to 59)

For Samples 42 to 59, sintered body samples were fabricated in a similar manner to Sample 36 except that the volume ratio of phosphor powder and AlN powder and the thickness of the samples were changed to the values indicated in Table 3. Specifically, the sintered body samples were fabricated with the volume ratio of phosphor powder and AlN powder set to 70:30, 60:40, or 50:50 and with the thickness of the samples set to 100 μm, 120 μm, 180 μm, 240 μm, 300 μm, or 360 μm at each volume ratio.

### (Sample 60)

In fabrication of Sample 60, mixed powder was heated to be sintered in a similar manner to Sample 36, and the obtained phosphor was pulverized in a mortar to obtain phosphor powder. This phosphor powder was not mixed with AlN powder, and the phosphor powder was pulverized with use of a ball mill.

Then, the phosphor powder pulverized with use of a ball mill was charged into a mold of ϕ20 mm, and the powder was molded at a molding pressure of 10 MPa to obtain a primary molded body. Thereafter, a sintered body sample was fabricated in a similar manner to Sample 36.

### (Sample 61)

Except that Al₂O₃ power, instead of AlN powder, was mixed with phosphor powder, a sintered body sample of Sample 61 was fabricated in a similar manner to Sample 44, that is, with the volume ratio of the phosphor powder and the thermal conduction powder set to 70:30 and with the thickness of the sample set to 180 μm.

Thus far, methods of fabricating the samples have been described. The evaluation results will be described below.

The samples from Samples 36 to 59, containing AlN powder, all had a thermal conductivity exceeding the reference value and had a good thermal conductivity. Furthermore, the samples having a volume fraction of AlN powder of 10 vol % to 40 vol % and having a thickness of 120 μm to 300 μm were all evaluated to have a good thermal conductivity, transmittance, absorptance, handleability, and effective luminous flux. The evaluation results will be described below in further detail.

Sample 60, containing no thermal conduction powder, was evaluated to have a good transmittance, absorptance, handleability, and effective luminous flux but was not evaluated to have a good thermal conductivity. Sample 61 includes Al₂O₃ powder having a thermal conductivity higher than the thermal conductivity of the phosphor. Therefore, the thermal conductivity of Sample 61 was higher than the thermal conductivity of Sample 60, but Sample 61 was not evaluated to have a good thermal conductivity.

Compared to the sample according to Sample 61, the thermal conduction powder is changed from Al₂O₃ powder to AlN powder in Sample 44. Since the thermal conductivity of AlN is higher than the thermal conductivity of Al₂O₃, the thermal conductivity of Sample 44 was higher than the thermal conductivity of Sample 61 and resulted in a good value.

Furthermore, the thermal conductivity resulted in a good value (>30 W/mK) in all of Samples 36 to 59, which included AlN powder. This shows that the thermal conductivity of a sample results in a good value when the volume fraction of at least AlN powder is no lower than 10 vol %.

Of Samples 42 to 59, in which the volume fraction of AlN powder was no lower than 30 vol %, the samples having a thickness of 360 μm had a transmittance of lower than 70%, but the samples having a thickness of no greater than 300 μm had a transmittance of a good value.

Of Samples 54 to 59, in which the volume fraction of AlN powder was 50 vol %, the samples having a thickness of 100 μm to 300 μm had an absorptance of lower than 78%, but the samples having a thickness of 360 μm resulted in a good absorptance. In the samples having a thickness of 100 μm to 300 μm, a leak of light through a side surface of the samples was suppressed, and the samples resulted in a good effective luminous flux.

Furthermore, while the samples having a thickness of less than 120 μm had a low mechanical strength and did not result in a good handleability, the samples having a thickness of no less than 120 μm did not sustain damage even when handled with tweezers and resulted in a good handleability.

### (Sample 62)

The light emitting module described with reference to FIG. 9 was fabricated as Sample 62. Specifically, with a sintered body that included phosphor powder and AlN powder and was fabricated under the condition similar to Sample 43 used as an optical wavelength conversion layer, the optical wavelength conversion layer was bonded at normal temperature to a sapphire mounting board such that the optical wavelength conversion layer covered the light emitting surface of a blue LED (peak wavelength: 460 nm), and thus a white light emitting module was fabricated.

With Sample 62, the chromaticity of the emission color of the light emitting module was within the range for the chromaticity suitable for a headlamp, and the chromaticity (cx,cy) was (0.32, 0.33). Accordingly, in the present example, as a fluorescent member according to one embodiment of the present disclosure is mounted on a blue LED, a white LED that excels in high-temperature characteristics and that is suitable for a specific use (e.g., vehicle headlight) can be fabricated.

Thus far, the present invention has been described with reference to the foregoing embodiments. The present invention, however, is not limited to the foregoing embodiments and also encompasses an embodiment obtained by combining configurations of the foregoing embodiments as appropriate. Furthermore, it is also possible to change the combinations or processing orders of the embodiments or to add modifications, such as various design changes, to the foregoing embodiments based on the knowledge of a person skilled in the art, and an embodiment obtained by adding such modifications may also be encompassed by the scope of the present invention.

In the foregoing embodiments, a sintered body has been described as one example of a fluorescent member that includes phosphor powder and thermal conduction powder. This is not a limiting example, and, for example, a member in which phosphor powder and thermal conduction powder are dispersed in a resin may serve as a fluorescent member.

What is claimed is:

1. A phosphor, wherein the phosphor
has a crystal structure of a garnet type, and
is expressed by a general formula BaₐY_{3-a-b}Al₅₋ₐSiₐO₁₂:Ce_{b} (wherein a and b are values within a range that satisfies 12.0113≤S+0.036b−0.003a≤12.0153, when S denotes a lattice size of the crystal structure, a [mol] denotes an amount of Ba incorporated in solid solution, and b [mol] denotes an amount of Ce incorporated in solid solution).

2. The phosphor according to claim 1, wherein
the phosphor is excited by blue light having a peak wavelength within a range of 430 nm to 480 nm and emits yellow light having a dominant wavelength within a range of 567 nm to 572 nm.

3. The phosphor according to claim 1, wherein
the amount a [mol] of Ba incorporated in solid solution is no greater than 1.0.

4. The phosphor according to claim 1, wherein
a mean volume diameter is 1 μm to 30 μm.

5. A fluorescent member, comprising:
phosphor powder, the phosphor powder being powder of the phosphor according to claim 1; and
thermal conduction powder, the thermal conduction powder being powder including a compound having a thermal conductivity higher than a thermal conductivity of the phosphor.

6. The fluorescent member according to claim 5, wherein
a volume ratio of the phosphor powder and the thermal conduction powder is within a range of 90:10 to 60:40.

7. The fluorescent member according to claim 5, wherein
the phosphor powder absorbs light having a peak wavelength of 450 nm,
the fluorescent member has a thickness of 0.12 mm to 0.30 mm, and
the fluorescent member has a transmittance of no less than 70% to light having a wavelength of 550 nm to 600 nm.

8. The fluorescent member according to claim 5, wherein
the phosphor powder absorbs blue light having a peak wavelength of 450 nm, and
the fluorescent member has an absorptance of 78% to 88% to the blue light.

9. A fluorescent member, comprising:
a resin transparent to visible light; and
the phosphor according to claim 1 encapsulated in the resin, wherein
the phosphor is contained in the resin at 0.1 vol % to 30 vol %, and
the fluorescent member has a thickness of 0.01 mm to 5 mm.

10. A light emitting module, comprising:
an LED that emits blue light having a peak wavelength within a range of 430 nm to 480 nm; and
an optical wavelength conversion layer that is excited by the blue light that the LED emits and emits yellow light, wherein
the optical wavelength conversion layer includes the fluorescent member according to claim 5, and
an emission color resulting from mixing the blue light and the yellow light has a chromaticity within a range defined by chromaticity coordinates (cx,cy)=(0.311, 0.339), (0.313, 0.342), (0.331, 0.354), (0.331, 0.338), (0.319, 0.315), (0.311, 0.309).
